(19) United States
(12) Patent Application Publication
(10) Pub. No.: US 2012/0212245 A1
(43) Pub. Date: Aug. 23, 2012

(54) CIRCUIT AND METHOD FOR TESTING INSULATING MATERIAL

(75) Inventors: Angelo Pinto, San Diego, CA (US); Martin L. Villafana, Bonita, CA (US); You-Wen Yau, San Diego, CA (US); Homyar C. Mogul, San Diego, CA (US); Lavakumar Ranganathan, San Diego, CA (US); Rohan V. Gupte, San Diego, CA (US); Weijia Qi, San Diego, CA (US); Kent J. Pingrey, San Diego, CA (US); Carlos P. Aguilar, San Diego, CA (US); Paul J. Giotta, Redington Beach, FL (US); Leon Y. Leung, San Diego, CA (US); Jina M. Antosz, Escondido, CA (US); Bhupen M. Shah, Carlsbad, CA (US); Choh fei Yeap, San Diego, CA (US); Michael J. Campbell, Encinitas, CA (US); Lawrence A. Elugbadebo, San Diego, CA (US); Allen A.B. Hogan, San Diego, CA (US)

(73) Assignee: QUALCOMM Incorporated, San Diego, CA (US)

(21) Appl. No.: 13/364,091

(22) Filed: Feb. 1, 2012

Related U.S. Application Data
(60) Provisional application No. 61/445,486, filed on Feb. 22, 2011.

(51) Int. Cl. G01R 31/3187; H01L 23/58

(52) U.S. Cl. 324/750.3; 257/48; 257/E23.002

(57) ABSTRACT

An integrated circuit is disclosed. The integrated circuit includes an insulating material layer. The integrated circuit also includes a metal structure. Furthermore, the integrated circuit includes a via through the insulating material layer that is coupled to the metal structure for testing insulating material by applying dynamic voltage switching to two adjacent metal components of the metal structure.

### RELATED APPLICATIONS

This application is related to and claims priority from U.S. Provisional Patent Application Ser. No. 61/445,486 filed Feb. 22, 2011 for “EFFECTIVE METAL-LOW DIELECTRIC CONSTANT INSULATING LAYER PROCESS WEAKNESS MONITOR METHOD.”

### TECHNICAL FIELD

The present disclosure relates generally to electronic devices. More specifically, the present disclosure relates to a circuit and method for testing insulating material.

### BACKGROUND

In the last several decades, the use of electronics has become common. In particular, advances in electronic technology have reduced the cost of increasingly complex and useful electronic devices. Cost reduction and consumer demand have proliferated the use of electronic devices such that they are practically ubiquitous in modern society. As the use of electronic devices has expanded, so has the demand for new and improved features of electronics. More specifically, electronic devices that perform functions faster, more efficiently or with higher quality are often sought after.

One kind of electronic device is an integrated circuit. As electronic technology has advanced, demand has arisen for integrated circuits that are smaller in size, that operate more efficiently and/or that perform operations more quickly. For example, integrated circuits that are smaller in size and/or that operate more efficiently may be beneficially used in portable devices such as cellular phones, smartphones and laptop computers. In this example, such integrated circuits may provide increased mobility and longer battery life, while providing increased performance.

However, many challenges have arisen as integrated circuits have been reduced in size. For example, manufacturing smaller integrated circuits may be more difficult. For instance, manufacturing processes may need to be carefully monitored and tuned to assure proper operation and desirable performance from smaller integrated circuits. As can be observed from this discussion, systems and methods that help test integrated circuits may be beneficial.

### SUMMARY

An integrated circuit is described. The integrated circuit includes an insulating material layer. The integrated circuit also includes a metal structure. The integrated circuit further includes a via through the insulating material layer that is coupled to the metal structure for testing insulating material by applying dynamic voltage switching to two adjacent metal components of the metal structure. The insulating material may be included in a wafer.

The metal structure may include a meander. The metal structure may include a comb structure. The metal structure may include a jog structure. The integrated circuit may include a plurality of vias coupled to the metal structure through the insulating material layer. The integrated circuit may also include one or more additional metal structures on one or more additional levels. The metal structure may be coupled to the one or more additional metal structures by the via.

Testing the insulating material may include measuring a leakage current from the metal structure before and after applying dynamic voltage switching to determine a leakage current change. Testing the insulating material may further include determining whether the insulating material has passed a test based on the leakage current change. Applying dynamic voltage switching may include applying voltage that varies between a positive voltage and a negative voltage between the two adjacent metal components. Applying dynamic voltage switching may include applying voltage that conforms to one of a group consisting of a square wave, a sinusoid, a triangle wave and a sawtooth wave.

An apparatus is also described. The apparatus includes means for testing insulating material. The means for testing insulating material includes means for insulating a metal structure. The means for testing insulating material also includes means for coupling the metal structure through the means for insulating the metal structure. The means for testing insulating material further includes means for applying dynamic voltage switching to two adjacent metal components of the metal structure.

A method for testing insulating material is also described. The method includes applying dynamic voltage switching to two adjacent metal components of a metal structure in an integrated circuit. The method also includes measuring a leakage current from the metal structure before and after applying dynamic voltage switching to determine a leakage current change. The method further includes determining whether insulating material has passed a test based on the leakage current change.

A computer-program product for testing insulating material is also described. The computer-program product includes a non-transitory tangible computer-readable medium with instructions. The instructions include code for causing an electronic device to apply dynamic voltage switching to two adjacent metal components of a metal structure in an integrated circuit. The instructions also include code for causing the electronic device to measure a leakage current from the metal structure before and after applying dynamic voltage switching to determine a leakage current change. The instructions further include code for causing the electronic device to determine whether insulating material has passed a test based on the leakage current change.

### BRIEF DESCRIPTION OF THE DRAWINGS

FIG. 1 is a block diagram illustrating one configuration of an integrated circuit that may be used for testing insulating material;

FIG. 2 is a block diagram illustrating a more specific configuration of an integrated circuit that may be used for testing insulating material;

FIG. 3 is a flow diagram illustrating one configuration of a method for testing insulating material;

FIG. 4 is a block diagram illustrating one example of an integrated circuit that may be used for testing insulating material;

FIG. 5 is a block diagram illustrating another example of an integrated circuit that may be used for testing insulating material;

FIG. 6 is a block diagram illustrating another example of an integrated circuit that may be used for testing insulating material;

FIG. 7 is a block diagram illustrating another example of an integrated circuit that may be used for testing insulating material;

FIG. 8 is a block diagram illustrating another example of an integrated circuit that may be used for testing insulating material;

FIG. 9 is a block diagram illustrating another example of an integrated circuit that may be used for testing insulating material;

FIG. 10 is a block diagram illustrating one or more electronic devices and another example of an integrated circuit that may be used for testing insulating material; and

FIG. 11 illustrates various components that may be utilized in an electronic device.

### DETAILED DESCRIPTION

It should be noted that the terms “couple,” “coupling,” “coupled” or other variations of the word couple as used herein may indicate either an indirect connection or a direct connection. For example, if a first component is “coupled” to a second component, the first component may be either indirectly connected (e.g., through another component) to the second component or directly connected to the second component.

It should be noted that as used herein, designating a component, element or entity (e.g., structure, metal line, transistor, capacitor, resistor, power supply, circuit, etc.) as a “first,” “second,” “third” or “fourth” component may be arbitrary and may be used to distinguish components for explanatory clarity. It should also be noted that labels used to designate a “second,” “third” or “fourth,” etc., do not necessarily imply that elements using preceding labels “first,” “second” or “third,” etc., are included or used. For example, simply because an element or component is labeled a “third” component does not necessarily imply that “first” and “second” elements or components exist or are used. In other words, the numerical labels (e.g., first, second, third, fourth, etc.) are labels that may be used for ease in explanation and may not necessarily imply a particular number of elements or a particular structure.

One configuration of the systems and methods disclosed herein may allow effective metal-low dielectric constant (e.g., “low K”) insulating layer process weakness monitoring. For example, the systems and methods disclosed herein may be applied to an integrated circuit comprising copper metal and low K dielectric insulating material. As used herein, “K” may denote a dielectric constant or relative permittivity. For instance, a “low K” dielectric may be an insulating material that has a lower dielectric constant than silicon dioxide.

The systems and methods disclosed herein may be used to detect reliability test failures in a silicon technology node due to metal (e.g., copper) and inter-metal low dielectric constant insulating material (e.g., low K insulating material) weaknesses and/or process shifts. For example, weaknesses or defects may occur where copper diffuses into low dielectric constant insulating material between two metal lines. This may create a weak or a failing spot for the circuit. In some cases, such weaknesses or failures may be observed using Transmission Electron Microscopy (TEM).

High temperature operating life (HTOL) reliability test failures were found in products designed with a 45 nanometer (nm) silicon technology node due to metal (e.g., copper) and inter-metal low dielectric constant insulating material weaknesses and/or process shifts. Traditionally, test structures such as metal comb-serpent-comb, comb-comb, or comb-serpent structures have been used. Typically, a direct current (DC) bias may be applied across adjacent electrically unconnected metal patterns in the structures. The DC bias values may be varied, typically from low to high. Leakage current may then have been measured across the metal pattern as the DC bias voltage is increased. If the leakage current exceeds the initial time (e.g., “time 0”) level by certain percentage, it may be deemed a “failure” in an integrated circuit or insulating material. Otherwise, the integrated circuit or insulating material may be deemed reliable.

In some configurations, the systems and methods disclosed herein may be based on silicon technology and may be applicable to silicon technology manufacturing process monitoring and any product using silicon technology. The systems and methods disclosed herein may provide a test structure for monitoring silicon technology process robustness. For example, the systems and methods disclosed herein may be used in silicon manufacturing facilities such as foundries.

The systems and methods disclosed herein may provide an effective, quick in-line monitor to detect process weaknesses early. This may reduce or minimize the impact to the manufacturing line and the product reliability due to poor metal, insulating dielectric layer process(es) and/or process shifts in the line. Increasingly smaller metal-to-metal spacing and more porous low dielectric constant insulating layer material may likely make this even worse as the silicon technology (e.g., minimum feature size) continues to shrink. For example, silicon technology may continue to shrink from 45 nm to 28 nm to 20 nm, where metal-to-metal spacing may also shrink with a similar ratio.

Product operating life reliability tests may typically be performed at elevated temperatures and bias voltages to simulate/accelerate product lifetime and failure rate. These tests may require more extraneous setup and long turn around time, including the test and the associated failure analysis. When defects such as those described above are found, there are often many wafers in the manufacturing process that can be adversely impacted. Such an impact can significantly jeopardize business as product shipments may be interrupted. Quick, effective and early detection and/or monitoring procedures may be needed to control the manufacturing process such that product reliability risks may be mitigated as early as possible and supply-chain integrity and/or business reputation may be maintained.

The systems and methods disclosed herein may be used for wafer-level testing. For example, the tests described herein may be done in-line at the wafer level. Thus, quick feedback may be provided regarding the metal and/or low dielectric constant insulating layer integrity. The systems and methods disclosed herein may be applicable to any and/or all metal levels separated by a dielectric (e.g., insulating) layer. In one configuration, a voltage bias may be alternated at adjacent metal lines. This may accelerate metal ion diffusion from a metal line to an inter-metal dielectric area and form a more “visible” or detectable defect. In one configuration, the systems and methods disclosed herein may be effective in 45 nm products.

Various configurations are now described with reference to the Figures, where like reference numbers may indicate functionally similar elements. The systems and methods as generally described and illustrated in the Figures herein could be arranged and designed in a wide variety of different configurations. Thus, the following more detailed description of several configurations, as represented in the Figures, is not intended to limit scope, as claimed, but is merely representative of the systems and methods.

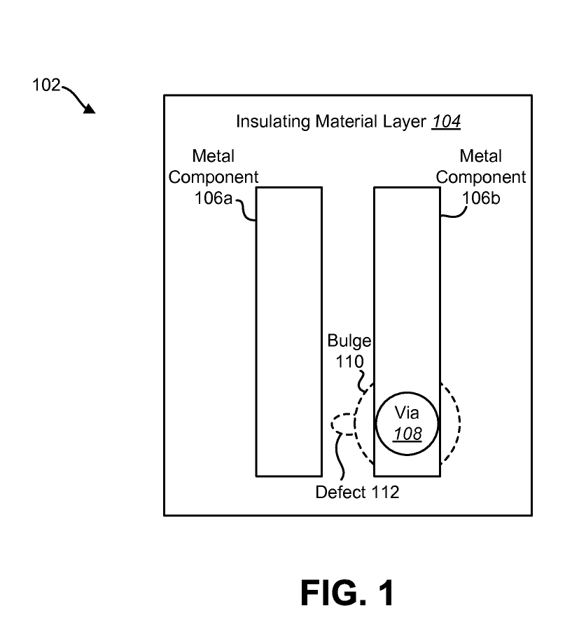

FIG. 1 is a block diagram illustrating one configuration of an integrated circuit 102 that may be used for testing insulating material. The integrated circuit 102 may comprise an insulating material layer 104. In some configurations, the insulating material layer 104 may comprise a “low K” dielectric that may be used to insulate metal components (e.g., lines) from each other.

The integrated circuit 102 may include a metal structure 106. It should be noted that the insulating material layer 104 may be above, below and/or at the same level as the metal structure 106. A metal structure 106 may include one or more metal components 106a-b (e.g., lines). In some configurations, the metal components 106a-b may run adjacent to each other, separated by an amount of insulating material. It should be noted that the insulating material may or may not be part of the insulating material layer 104. For example, insulating material for testing (which may or may not be between the metal components 106a-b) may or may not be part of the insulating material layer 104. In some configurations, the insulating material (for testing) is included in a wafer. In the configuration illustrated in FIG. 1, a first metal component 106a and a second metal component 106b may run approximately adjacent to each other, separated by a space filled by insulating material. For instance, the metal components 106a-b may be copper lines separated by a low K dielectric insulating material. In some configurations, the space between the metal components 106a-b may be a minimum space allowed according to a manufacturing process (e.g., line-to-line spacing allowed by minimum design rules). It should be noted that the integrated circuit 102 (e.g., insulating material) may be included in a wafer with additional components and/or circuitry in some configurations. For instance, the metal structure 106 may be included in a wafer that includes other components, such as transistors, capacitors, resistors, inductors, metal lines, etc.

Other configurations of metal structures 106 may be used. For example, the metal components 106a-b may include bends, angles, turns, etc. It should be noted that a metal “component” or “line” as described herein may or may not be entirely straight. For instance, the metal structure 106 may additionally or alternatively comprise one or more lines, meanders, jogs, hammerheads, combs, “serpents,” etc. Additional examples are given below in connection with additional Figures.

The metal structure 106 may be coupled to one or more vias 108. A via 108 may run through the insulating material layer 104 and may be coupled to the metal structure 106. For example, the via 108 may be placed above or below the metal structure 106 through the insulating material layer 104. In some configurations, the via 108 may couple the metal structure 106 to another (e.g., additional) metal structure on a different (e.g., additional) level. For instance, another metal structure that is above or below (on another level from) the metal structure 106 illustrated may be coupled to the metal structure 106 by the via 108 through the insulating material layer 104. The metal structure on a different level may be similar to or dissimilar from the metal structure 106 illustrated. In some configurations, one or more vias (e.g., via 108) may be coupled to a metal structure (e.g., metal structure 106) at a location on one metal component (e.g., the second metal component 106b) that is adjacent to another metal component (e.g., the first metal component 106a). Some examples of this are illustrated in FIGS. 1-2 and 4-10.

When a via 108 is added to the integrated circuit 102, a bulge 110 of metal may be formed. In other words, the bulge 110 may be the via 108 itself and/or may be caused by installation of the via 108. Vias may or may not be precisely circular or columnar in shape in some instances. For example, a via 108 may take on a conical shape in some instances. One or more vias illustrated in the Figures described herein may include each include a bulge. For simplicity, however, one or more of the vias described herein may be illustrated as a circle without a bulge in the Figures.

As can be observed from the example illustrated in FIG. 1, the bulge 110 may cause the second metal component 106b to come close to the first metal component 106a. This may reduce the space or gap of insulating material between the two metal components 106a-b. In some cases, a defect 112 may form in the integrated circuit 102. For example, a defect 112 may be formed where metal (e.g., copper) diffuses into the insulating material (e.g., low K insulating material) between the metal components 106a-b. The defect 112 may be formed, for instance, when one or more manufacturing processes are not controlled properly. In the example illustrated in FIG. 1, the defect 112 protrudes from the bulge 110 (e.g., via 108). However, a defect 112 may protrude from another part of the metal structure 106. In some cases, a defect 112 may cause degraded functionality in the integrated circuit 102. For example, a defect 112 may cause leakage (e.g., current leakage), a short and/or failing functionality.

Accordingly, using one or more vias 108 with a metal structure 106 for testing in an integrated circuit 102 may allow detection of manufacturing process deficiencies. For example, the metal structure 106 with a via 108 may be used to test the insulating material (e.g., integrated circuit 102) for manufacturing process (e.g., insulating material) quality. In one configuration, a voltage may be applied and/or varied between the metal components 106a-b for testing. For example, a direct current (DC) voltage and/or a dynamic switched voltage may be applied to the metal structure 106. A leakage current in the metal structure may be measured before and after applying the voltage to determine a leakage current change. The leakage current change may be used to determine whether or not the insulating material (e.g., integrated circuit 102) has passed the test. For instance, a leakage current may be used to determine whether one or more predetermined criteria for passing the test are met.

In order to test the insulating material (e.g., integrated circuit 102), an electronic device may be coupled to the metal structure 106. For example, an electronic device may be coupled to the first metal component 106a and to the second metal component 106b. The electronic device may apply the voltage (e.g., dynamic switched voltage) between the metal components 106a-b, measure leakage current and/or determine whether the insulating material (e.g., integrated circuit 102) has passed or failed the test.

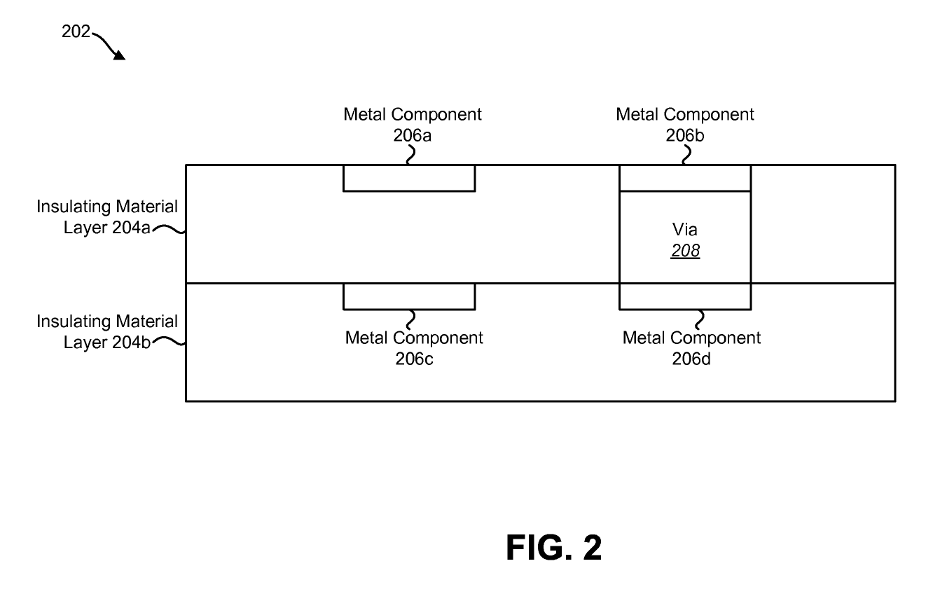

FIG. 2 is a block diagram illustrating a more specific configuration of an integrated circuit 202 that may be used for testing insulating material. The integrated circuit 202 may comprise multiple insulating material layers 204a-b. In some configurations, the insulating material layers 204a-b may comprise a “low K” dielectric that may be used to insulate metal components (e.g., lines) from each other.

A first insulating material layer 204a may include a first metal structure 206a-b. In this example, the first metal structure 206a-b may be embedded in the first insulating material layer 204a. Furthermore, the first insulating material layer 204a is below the first metal structure 206a-b and above a second insulating material layer 204b. A second insulating material layer 204b may include a second metal structure 206c-d. In this example, the second metal structure 206c-d may be embedded in the second insulating material layer 204b. Furthermore, the second insulating material layer 204b is below the second metal structure 206c-d. The first metal structure 206a-b includes two metal components 206a-b (e.g., lines). The top layer of the integrated circuit 202 may be similar to integrated circuit 102 illustrated in FIG. 1, though FIG. 2 provides a side “cutaway” view.

In the configuration illustrated in FIG. 2, the metal components 206a-b in the first metal structure 206a-b run adjacent to each other, separated by an amount of insulating material in the first insulating material layer 204a. Furthermore, the metal components 206c-d in the second metal structure 206c-d run adjacent to each other, separated by an amount of insulating material in the second insulating material layer 204b. Additionally, the first metal structure 206a-b is separated from the second metal structure 206c-d by the first insulating material layer 204a (except where coupled together by the via 208). In one configuration, the metal components 206a-d may be copper lines separated by a low K dielectric insulating material (in the insulating material layers 204a-b, for example). In some configurations, the space between the metal components 206a-b in the first insulating material layer 204a and the space between the metal components 206c-d in the second insulating material layer 204b may be a minimum space allowed according to a manufacturing process (e.g., line-to-line spacing allowed by minimum design rules).

The first metal structure 206a-b may be coupled to the second (e.g., additional) metal structure 206c-d using a via 208. The via 208 runs through the first insulating material layer 204a. For example, the via 208 couples a metal component 206b in the first metal structure 206a-b to another metal component 206d in the second metal structure 206c-d. Thus, the via 208 couples the first metal structure 206a-b on one level to the second (e.g., additional) metal structure 206c-d on a different (e.g., additional) level. It should be noted that one or more additional metal structures on one or more additional levels may be used. One or more vias may be used to couple the additional metal structures to the first metal structure 206a-b and/or the second metal structure 206c-d.

When the via 208 is added to the integrated circuit 202, a bulge of metal may be formed. Vias may or may not be precisely circular or columnar in shape in some instances. For example, the via 208 may take on a conical shape in some instances. Although the via 208 is illustrated without a bulge, the via 208 may bulge outwards. The bulge may cause the second metal component 206b to come close to the first metal component 206b and/or to the third metal component 206c. This may reduce the space or gap of insulating material between the metal components 206a-b, 206c-d. In some cases, a defect may form in the integrated circuit 202. For example, a defect may be formed where metal (e.g., copper) diffuses into the insulating material (e.g., low K insulating material) between the metal components 206. In some cases, a defect may cause degraded functionality in the integrated circuit 202. For example, a defect may cause leakage (e.g., current leakage), a short and/or failing functionality.

Accordingly, using the via 208 between the metal structures 206 in an integrated circuit 202 may allow detection of manufacturing process deficiencies. For example, the metal structure 206 with a via 208 may be used to test the insulating material (e.g., integrated circuit 202) for manufacturing process quality. In one configuration, a voltage may be applied and/or varied between the first and second metal components 206a-b and/or between the third and fourth metal components 206c-d for testing. For example, a direct current (DC) voltage and/or a dynamic switched voltage may be applied to the metal structures 206. A leakage current in the metal structures 206 may be measured before and after applying the voltage to determine a leakage current change. The leakage current change may be used to determine whether or not the insulating material (e.g., integrated circuit 202) has passed the test. For instance, a leakage current may be used to determine whether one or more predetermined criteria for passing the test are met.

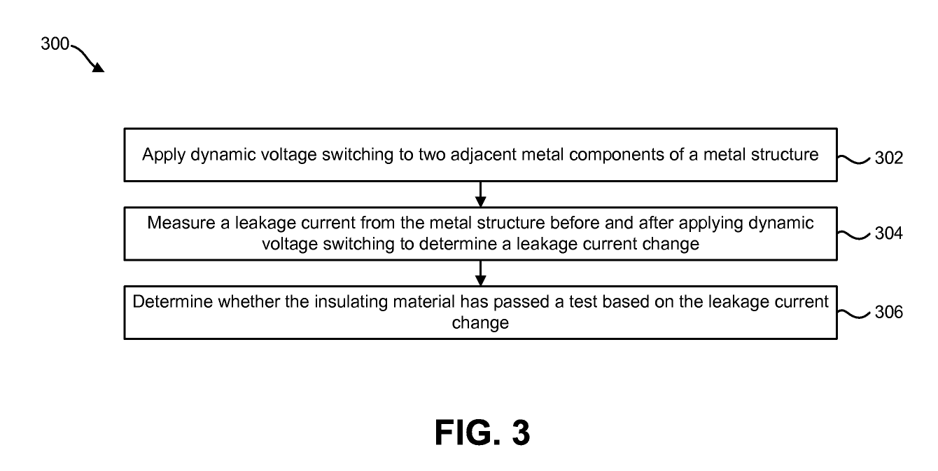

FIG. 3 is a flow diagram illustrating one configuration of a method 300 for testing insulating material. An electronic device (e.g., automated testing equipment or ATE) may apply 302 dynamic voltage switching to two adjacent metal components 106a-b of a metal structure 106 in an integrated circuit 102. Applying 302 dynamic voltage switching may comprise applying a voltage between two metal components that varies or switches polarity between a negative voltage and a positive voltage. This is different from the traditional approach that applies a DC voltage for testing.

Dynamic voltage switching may be applied 302 in accordance with one or more examples. In one example, the voltage applied 302 between the two adjacent metal components 106a-b may conform to a square wave that alternates between positive and negative voltages. In another example, the voltage applied 302 conforms to a sinusoid. In other examples, the voltage applied 302 may conform to triangular (e.g., triangle) waves, sawtooth waves and/or other signals that vary between positive and negative polarities. In some configurations, the voltage may vary in a regularly repeating pattern, with an established frequency and/or period. The frequency, period, phase and/or amplitude of the dynamic voltage switching may be adjustable in some configurations.

In some configurations, the electronic device (e.g., an ATE, an automatic test pattern generator, etc.) may apply 302 dynamic voltage switching according to a test pattern. Additionally or alternatively, the dynamic voltage switching may be applied 302 in a high temperature operating life (HTOL) test on two adjacent metal lines 106a-b in the metal structure 106 at high speed and at elevated temperature or room temperature. For instance, the HTOL test may be performed on an integrated circuit 102 that was manufactured using 45 nanometer (nm) technology. Using dynamic voltage switching may enhance metal/low dielectric constant insulating layer defects more effectively than the using the DC voltage approach. It should be noted that pulse width, pulse frequency and/or pulse polarity of the dynamic voltage switching may be modulated to obtain an improved or optimized result.

The electronic device may measure 304 a leakage current from the metal structure 106 before and after applying 302 dynamic voltage switching to determine a leakage current change. For example, the electronic device (e.g., an ATE) that is used for electric probing may measure 304 the leakage current. In one configuration, a voltage may be applied using a voltage source and the corresponding leakage current may be measured by a current measuring unit such as a ammeter. For instance, the electronic device may detect an amount of current flow from the first metal component 106a to the second metal component 106b or vice-versa. The leakage current may be measured 304 (and recorded, for example) before the dynamic voltage switching is applied 302. The leakage current may also be measured 304 after the dynamic voltage switching is applied 302. The leakage current measured 304 after applying 302 the dynamic voltage switching may be compared to (e.g., subtracted from) the leakage current measured 304 before applying 302 the dynamic switching voltage to determine a leakage current change.

The electronic device may determine 306 whether the insulating material (e.g., integrated circuit 102) has passed a test based on the leakage current change. For example, the leakage current change may be compared to a predetermined criterion for an acceptable amount of leakage current change. If the leakage current change is greater than the criterion, for example, the electronic device may determine 306 that the insulating material (e.g., integrated circuit 102) has failed the test. However, if the leakage current change is less than or equal to the criterion, for instance, the electronic device may determine 306 that the insulating material (e.g., integrated circuit 102) has passed the test. One or more additional or alternative predetermined criteria may be used to determine 306 whether the insulating material has passed the test.

It some configurations, one or more manufacturing procedures (e.g., “processes”) may be adjusted based on the results of the test. For example, the electronic device, another electronic device and/or a user may adjust one or more manufacturing procedures in order to reduce failures or improve the quality of integrated circuits if the electronic device determines 306 that the integrated circuit 102 has failed the test.

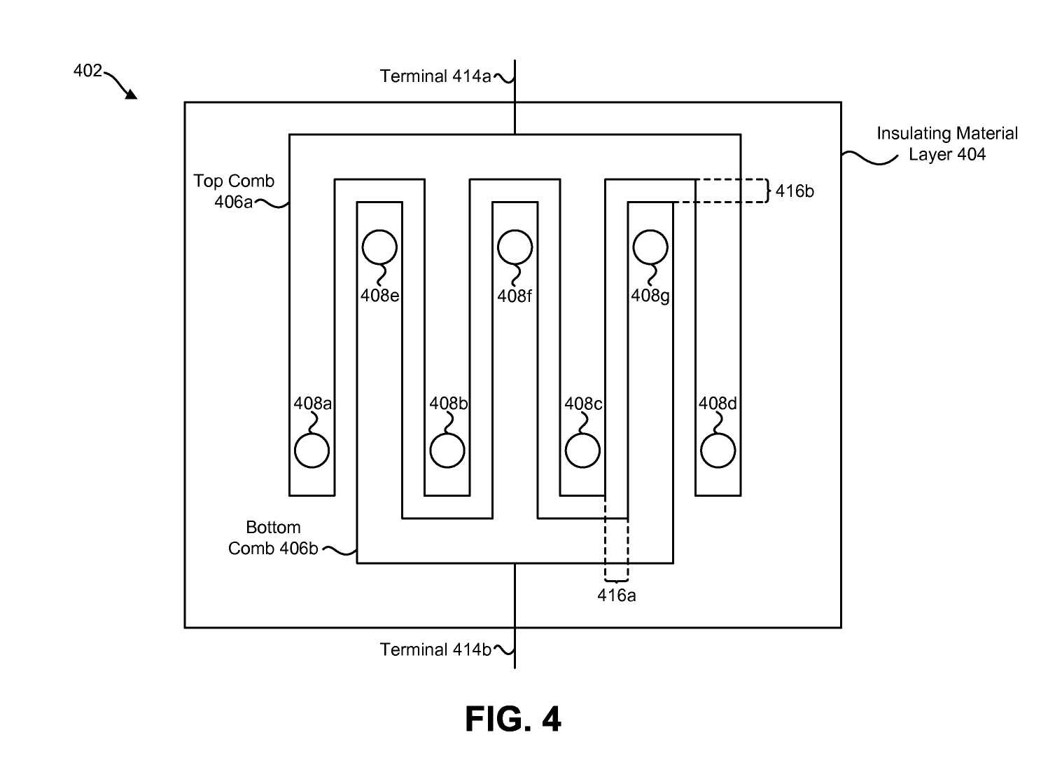

FIG. 4 is a block diagram illustrating one example of an integrated circuit 402 that may be used for testing insulating material. More specifically, FIG. 4 illustrates one kind of metal structure 406 that may be used in accordance with the systems and methods disclosed herein. The integrated circuit 402 may include an insulating material layer 404, which may be similar to the insulating material layer 104 described in connection with FIG. 1 above.

The metal structure 406 included in the integrated circuit 402 may be one example of a hammerhead structure. In particular, the example of the metal structure 406 illustrated includes a top comb structure 406a and a bottom comb structure 406b. The top comb structure 406a and the bottom comb structure 406b are located adjacent to each other and are intermingled. In one configuration, a first spacing 416a between the comb structures 406a-b may be a minimum line-to-line spacing allowed by design rules. Additionally or alternatively, a second spacing 416b may be a minimum line-to-line spacing allowed by design rules. Design rules, for example, may be established by an integrated circuit manufacturer and may specify a minimum line-to-line spacing between metal lines or components for a certain manufacturing technology node (e.g., 45 nm technology node, 28 nm technology node, 20 nm technology node, etc.).

In the example illustrated in FIG. 4, the metal structure 406 is coupled to multiple vias 408a-g. For instance, the top comb structure 406a may be coupled to four vias 408a-d, while the bottom comb structure 406b may be coupled to three vias 408e-g. The vias 408a-g may run through the insulating material layer 404, which may be above or below the metal structure 406. It should be noted that one or more of the vias 408 may cause and/or include a bulge similar to the bulge 110 illustrated in FIG. 1. In the example illustrated in FIG. 4, each via 408 may be near the end of a tine or prong of the comb structures 406a-b.

In some configurations, the integrated circuit 402 may include multiple levels of insulating materials and/or metal structures. For example, the metal structure 406 may be located on a fifth metal level (e.g., “metal 5”), and the vias 408a-g may underlie the metal structure 406. While the example of the fifth metal level is given, it should be noted that the metal structure 406 may occupy any level (e.g., any metal level) in an integrated circuit 402. In some configurations, the integrated circuit 402 may include the metal structure 406 in addition to one or more similar metal structures on one or more other levels that are coupled to the metal structure 406 (by the vias 408a-g, for example). For instance, the integrated circuit 402 may include five metal levels with the metal structure 406 on one level and four additional metal structures similar to the metal structure 406 on the other four metal levels. The metal levels may be insulated from each other by the insulating material layer 404 and additional layers of insulating material similar to the insulating material layer 404. Additional vias similar to the vias 408 illustrated may be used to couple metal structures to each other through additional layers of insulating material.

It should be noted that line lengths (e.g., dimensions of the metal structure 406) may vary. However, longer lengths (e.g., 10,000 micrometers (μm) or more) may be more effective.

As illustrated in FIG. 4, the top comb structure 406a may be coupled to a terminal 414a and the bottom comb structure 406b may be coupled to another terminal 414b. The terminals 414a-b may be pins, couplers, etc., that allow one or more electronic devices (e.g., an ATE) to be coupled to the metal structure 406. For example, the terminals 414a-b may allow an electronic device to apply a DC voltage and/or dynamic voltage switching between the top comb structure 406a and the bottom comb structure 406b.

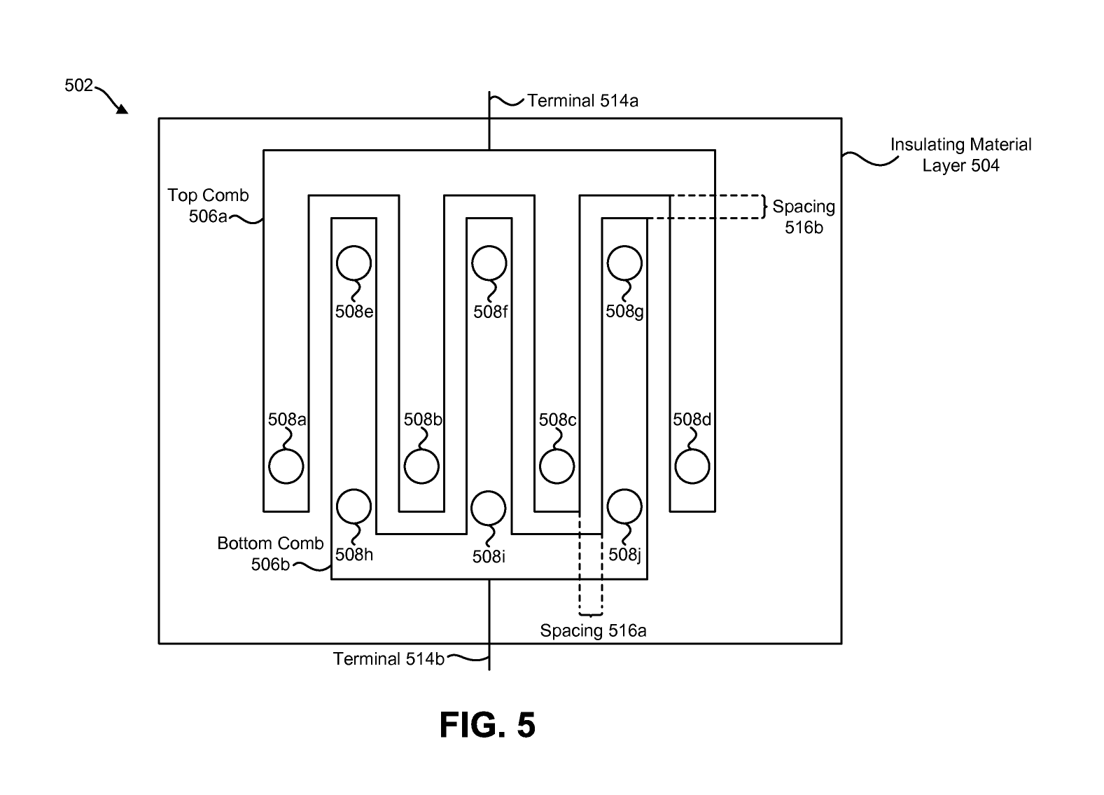

FIG. 5 is a block diagram illustrating another example of an integrated circuit 502 that may be used for testing insulating material. More specifically, FIG. 5 illustrates one kind of metal structure 506 that may be used in accordance with the systems and methods disclosed herein. The integrated circuit 502 may include an insulating material layer 504, which may be similar to the insulating material layer 104 described in connection with FIG. 1 above.

The metal structure 506 included in the integrated circuit 502 may be one example of a hammerhead structure. In particular, the example of the metal structure 506 illustrated includes a top comb structure 506a and a bottom comb structure 506b. The top comb structure 506a and the bottom comb structure 506b are located adjacent to each other and are intermingled. In one configuration, a first spacing 516a between the comb structures 506a-b may be a minimum line-to-line spacing allowed by design rules. Additionally or alternatively, a second spacing 516b may be a minimum line-to-line spacing allowed by design rules.

In the example illustrated in FIG. 5, the metal structure 506 is coupled to multiple vias 508a-j. For instance, the top comb structure 506a may be coupled to four vias 508a-d, while the bottom comb structure 506b may be coupled to six vias 508e-j. The vias 508a-j may run through the insulating material layer 504, which may be above or below the metal structure 506. It should be noted that one or more of the vias 508 may cause and/or include a bulge similar to the bulge 110 illustrated in FIG. 1. In the example illustrated in FIG. 5, some vias 508a-d, 508h-j are positioned in a staggered fashion on tines or prongs of the structure 506. Additionally or alternatively, the bottom comb structure 506b may include vias 508e-g near the end of its 506b tines or prongs.

In some configurations, the integrated circuit 502 may include multiple levels of insulating materials and/or metal structures. For example, the metal structure 506 may be located on a fifth metal level (e.g., “metal 5”), and the vias 508a-j may underlie the metal structure 506. While the example of the fifth metal level is given, it should be noted that the metal structure 506 may occupy any level (e.g., any metal level) in an integrated circuit 502. In some configurations, the integrated circuit 502 may include the metal structure 506 in addition to one or more similar metal structures on one or more other levels that are coupled to the metal structure 506 (by the vias 508a-j, for example). For instance, the integrated circuit 502 may include five metal levels with the metal structure 506 on one level and four additional metal structures similar to the metal structure 506 on the other four metal levels. The metal levels may be insulated from each other by the insulating material layer 504 and additional layers of insulating material similar to the insulating material layer 504. Additional vias similar to the vias 508 illustrated may be used to couple metal structures to each other through additional layers of insulating material.

It should be noted that line lengths (e.g., dimensions of the metal structure 506) may vary. However, longer lengths (e.g., 10,000 micrometers (μm) or more) may be more effective.

As illustrated in FIG. 5, the top comb structure 506a may be coupled to a terminal 514a and the bottom comb structure 506b may be coupled to another terminal 514b. The terminals 514a-b may be pins, couplers, etc., that allow one or more electronic devices (e.g., an ATE) to be coupled to the metal structure 506. For example, the terminals 514a-b may allow an electronic device to apply a DC voltage and/or dynamic voltage switching between the top comb structure 506a and the bottom comb structure 506b.

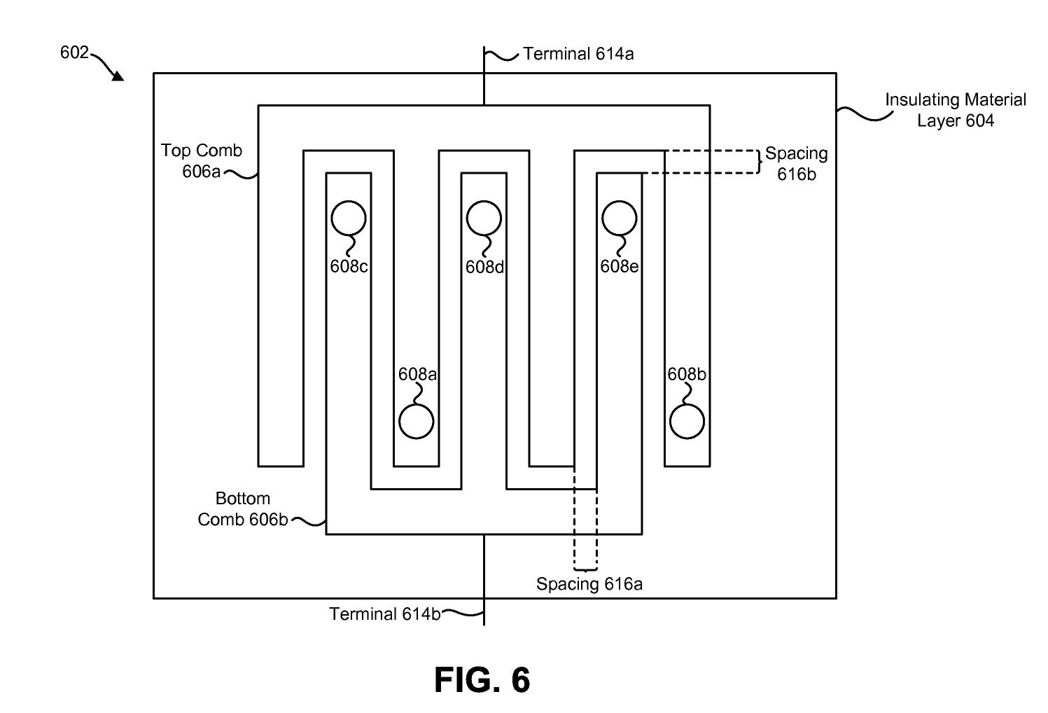

FIG. 6 is a block diagram illustrating another example of an integrated circuit 602 that may be used for testing insulating material. More specifically, FIG. 6 illustrates one kind of metal structure 606 that may be used in accordance with the systems and methods disclosed herein. The integrated circuit 602 may include an insulating material layer 604, which may be similar to the insulating material layer 104 described in connection with FIG. 1 above.

The metal structure 606 included in the integrated circuit 602 may be one example of a hammerhead structure. In particular, the example of the metal structure 606 illustrated includes a top comb structure 606a and a bottom comb structure 606b. The top comb structure 606a and the bottom comb structure 606b are located adjacent to each other and are intermingled. In one configuration, a first spacing 616a between the comb structures 606a-b may be a minimum line-to-line spacing allowed by design rules. Additionally or alternatively, a second spacing 616b may be a minimum line-to-line spacing allowed by design rules.

In the example illustrated in FIG. 6, the metal structure 606 is coupled to multiple vias 608a-e. For instance, the top comb structure 606a may be coupled to two vias 608a-b, while the bottom comb structure 606b may be coupled to three vias 608c-e. The vias 608a-e may run through the insulating material layer 604, which may be above or below the metal structure 606. It should be noted that one or more of the vias 608 may cause and/or include a bulge similar to the bulge 110 illustrated in FIG. 1. In the example illustrated in FIG. 6, some of the tines or prongs in the structure 606 do not include any vias, while other tines or prongs may include vias 608a-e (near the end of the tines or prongs, for example).

In some configurations, the integrated circuit 602 may include multiple levels of insulating materials and/or metal structures. For example, the metal structure 606 may be located on a fifth metal level (e.g., “metal 5”), and the vias 608a-e may underlie the metal structure 606. While the example of the fifth metal level is given, it should be noted that the metal structure 606 may occupy any level (e.g., any metal level) in an integrated circuit 602. In some configurations, the integrated circuit 602 may include the metal structure 606 in addition to one or more similar metal structures on one or more other levels that are coupled to the metal structure 606 (by the vias 608a-e, for example). For instance, the integrated circuit 602 may include five metal levels with the metal structure 606 on one level and four additional metal structures similar to the metal structure 606 on the other four metal levels. The metal levels may be insulated from each other by the insulating material layer 604 and additional layers of insulating material similar to the insulating material layer 604. Additional vias similar to the vias 608 illustrated may be used to couple metal structures to each other through additional layers of insulating material.

It should be noted that line lengths (e.g., dimensions of the metal structure 606) may vary. However, longer lengths (e.g., 10,000 micrometers (μm) or more) may be more effective.

As illustrated in FIG. 6, the top comb structure 606a may be coupled to a terminal 614a and the bottom comb structure 606b may be coupled to another terminal 614b. The terminals 614a-b may be pins, couplers, etc., that allow one or more electronic devices (e.g., an ATE) to be coupled to the metal structure 606. For example, the terminals 614a-b may allow an electronic device to apply a DC voltage and/or dynamic voltage switching between the top comb structure 606a and the bottom comb structure 606b.

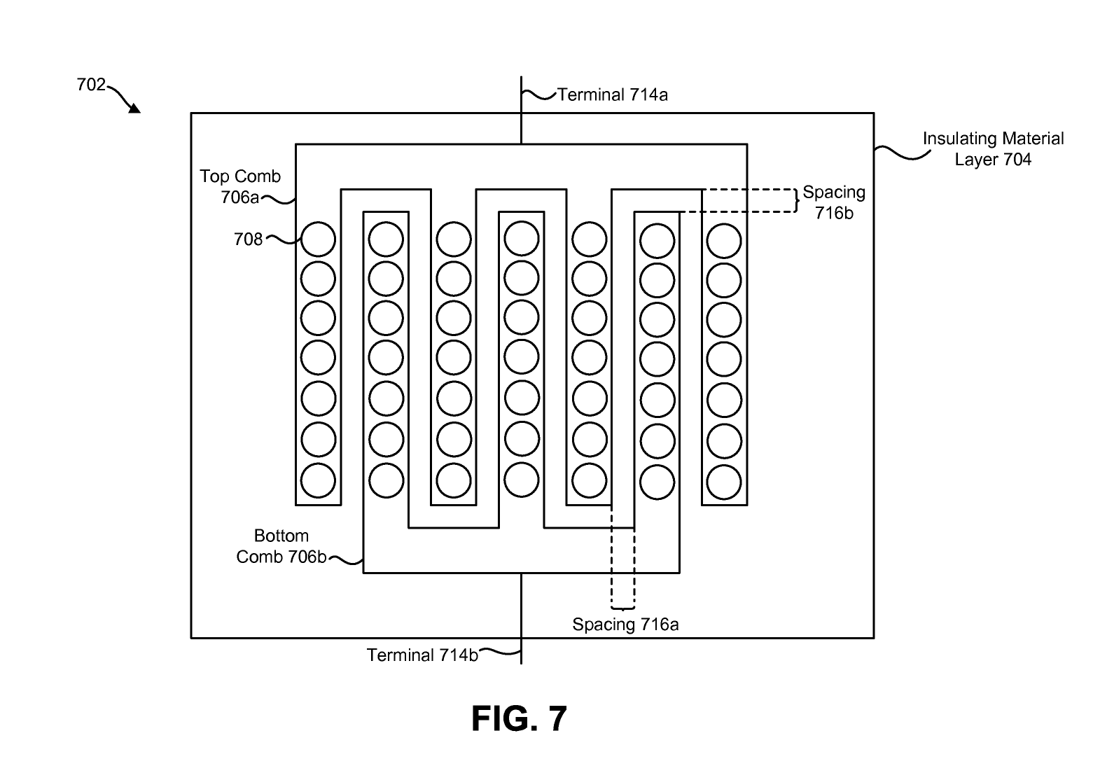

FIG. 7 is a block diagram illustrating another example of an integrated circuit 702 that may be used for testing insulating material. More specifically, FIG. 7 illustrates one kind of metal structure 706 that may be used in accordance with the systems and methods disclosed herein. The integrated circuit 702 may include an insulating material layer 704, which may be similar to the insulating material layer 104 described in connection with FIG. 1 above.

The metal structure 706 included in the integrated circuit 702 may be one example of a hammerhead structure. In particular, the example of the metal structure 706 illustrated includes a top comb structure 706a and a bottom comb structure 706b. The top comb structure 706a and the bottom comb structure 706b are located adjacent to each other and are intermingled. In one configuration, a first spacing 716a between the comb structures 706a-b may be a minimum line-to-line spacing allowed by design rules. Additionally or alternatively, a second spacing 716b may be a minimum line-to-line spacing allowed by design rules.

In the example illustrated in FIG. 7, the metal structure 706 is coupled to multiple vias 708. For instance, the top comb structure 706a may be coupled to 28 vias 708, while the bottom comb structure 706b may be coupled to 21 vias 708. It should be noted that the reference number 708 may be used herein to refer to one or more of the vias 708 illustrated in FIG. 7. The vias 708 may run through the insulating material layer 704, which may be above or below the metal structure 706. It should be noted that one or more of the vias 708 may cause and/or include a bulge similar to the bulge 110 illustrated in FIG. 1. In the example illustrated in FIG. 7, each of the tines or prongs in the structure 706 include multiple vias 708. Furthermore, the vias 708 are lined up across tines or prongs of the metal structure 706.

In some configurations, the integrated circuit 702 may include multiple levels of insulating materials and/or metal structures. For example, the metal structure 706 may be located on a fifth metal level (e.g., “metal 5”), and the vias 708 may underlie the metal structure 706. While the example of the fifth metal level is given, it should be noted that the metal structure 706 may occupy any level (e.g., any metal level) in an integrated circuit 702. In some configurations, the integrated circuit 702 may include the metal structure 706 in addition to one or more similar metal structures on one or more other levels that are coupled to the metal structure 706 (by the vias 708, for example). For instance, the integrated circuit 702 may include five metal levels with the metal structure 706 on one level and four additional metal structures similar to the metal structure 706 on the other four metal levels. The metal levels may be insulated from each other by the insulating material layer 704 and additional layers of insulating material similar to the insulating material layer 704. Additional vias similar to the vias 708 illustrated may be used to couple metal structures to each other through additional layers of insulating material.

It should be noted that line lengths (e.g., dimensions of the metal structure 706) may vary. However, longer lengths (e.g., 10,000 micrometers (μm) or more) may be more effective.

As illustrated in FIG. 7, the top comb structure 706a may be coupled to a terminal 714a and the bottom comb structure 706b may be coupled to another terminal 714b. The terminals 714a-b may be pins, couplers, etc., that allow one or more electronic devices (e.g., an ATE) to be coupled to the metal structure 706. For example, the terminals 714a-b may allow an electronic device to apply a DC voltage and/or dynamic voltage switching between the top comb structure 706a and the bottom comb structure 706b.

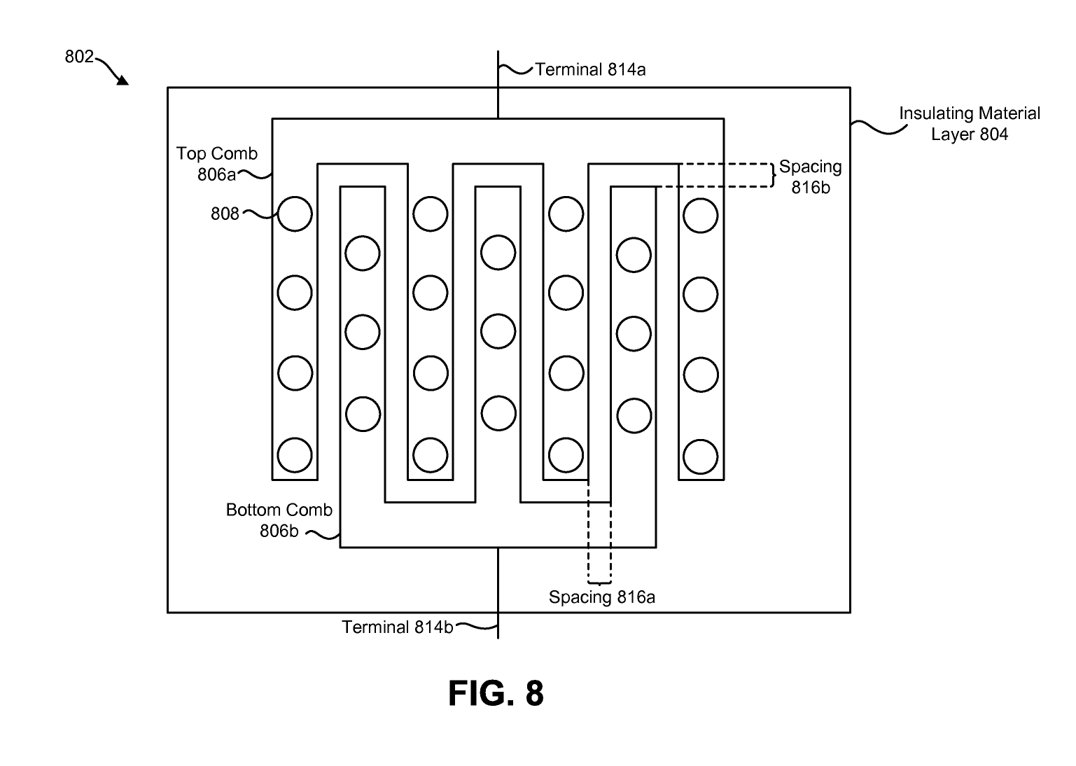

FIG. 8 is a block diagram illustrating another example of an integrated circuit 802 that may be used for testing insulating material. More specifically, FIG. 8 illustrates one kind of metal structure 806 that may be used in accordance with the systems and methods disclosed herein. The integrated circuit 802 may include an insulating material layer 804, which may be similar to the insulating material layer 104 described in connection with FIG. 1 above.

The metal structure 806 included in the integrated circuit 802 may be one example of a hammerhead structure. In particular, the example of the metal structure 806 illustrated includes a top comb structure 806a and a bottom comb structure 806b. The top comb structure 806a and the bottom comb structure 806b are located adjacent to each other and are intermingled. In one configuration, a first spacing 816a between the comb structures 806a-b may be a minimum line-to-line spacing allowed by design rules. Additionally or alternatively, a second spacing 816b may be a minimum line-to-line spacing allowed by design rules.

In the example illustrated in FIG. 8, the metal structure 806 is coupled to multiple vias 808. For instance, the top comb structure 806a may be coupled to 16 vias 808, while the bottom comb structure 806b may be coupled to 9 vias 808. It should be noted that the reference number 808 may be used herein to refer to one or more of the vias 808 illustrated in FIG. 8. The vias 808 may run through the insulating material layer 804, which may be above or below the metal structure 806. It should be noted that one or more of the vias 808 may cause and/or include a bulge similar to the bulge 110 illustrated in FIG. 1. In the example illustrated in FIG. 8, each of the tines or prongs in the structure 806 include multiple vias 808. Furthermore, the vias 808 are located in a staggered pattern across tines or prongs of the metal structure 806.

In some configurations, the integrated circuit 802 may include multiple levels of insulating materials and/or metal structures. For example, the metal structure 806 may be located on a fifth metal level (e.g., “metal 5”), and the vias 808 may underlie the metal structure 806. While the example of the fifth metal level is given, it should be noted that the metal structure 806 may occupy any level (e.g., any metal level) in an integrated circuit 802. In some configurations, the integrated circuit 802 may include the metal structure 806 in addition to one or more similar metal structures on one or more other levels that are coupled to the metal structure 806 (by the vias 808, for example). For instance, the integrated circuit 802 may include five metal levels with the metal structure 806 on one level and four additional metal structures similar to the metal structure 806 on the other four metal levels. The metal levels may be insulated from each other by the insulating material layer 804 and additional layers of insulating material similar to the insulating material layer 804. Additional vias similar to the vias 808 illustrated may be used to couple metal structures to each other through additional layers of insulating material.

It should be noted that line lengths (e.g., dimensions of the metal structure 806) may vary. However, longer lengths (e.g., 10,000 micrometers (μm) or more) may be more effective.

As illustrated in FIG. 8, the top comb structure 806a may be coupled to a terminal 814a and the bottom comb structure 806b may be coupled to another terminal 814b. The terminals 814a-b may be pins, couplers, etc., that allow one or more electronic devices (e.g., an ATE) to be coupled to the metal structure 806. For example, the terminals 814a-b may allow an electronic device to apply a DC voltage and/or dynamic voltage switching between the top comb structure 806a and the bottom comb structure 806b.

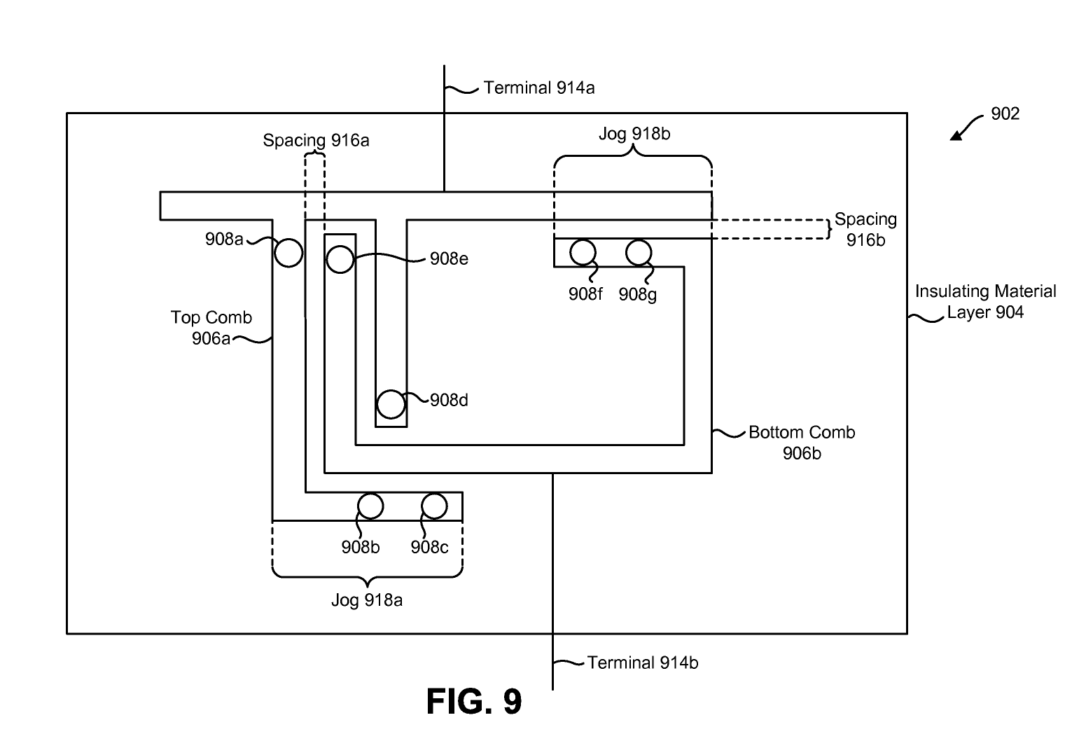

FIG. 9 is a block diagram illustrating another example of an integrated circuit 902 that may be used for testing insulating material. More specifically, FIG. 9 illustrates one kind of metal structure 906 that may be used in accordance with the systems and methods disclosed herein. The integrated circuit 902 may include an insulating material layer 904, which may be similar to the insulating material layer 104 described in connection with FIG. 1 above.

The metal structure 906 included in the integrated circuit 902 may illustrate one example of jog structures. In particular, the example of the metal structure 906 illustrated includes a top comb structure 906a with a jog structure 918a and a bottom comb structure 906b with a jog structure 918b. For example, a jog structure may comprise a bend, turn or angle in a metal component. The top comb structure 906a and the bottom comb structure 906b are located adjacent to each other and are intermingled. In one configuration, a first spacing 916a between the comb structures 906a-b may be a minimum line-to-line spacing allowed by design rules. Additionally or alternatively, a second spacing 916b may be a minimum line-to-line spacing allowed by design rules.

In the example illustrated in FIG. 9, the metal structure 906 is coupled to one or more vias 908. For instance, the top comb structure 906a may be coupled to four vias 908a-d, while the bottom comb structure 906b may be coupled to three vias 908e-g. The vias 908 may run through the insulating material layer 904, which may be above or below the metal structure 906. It should be noted that one or more of the vias 908a-g may cause and/or include a bulge similar to the bulge 110 illustrated in FIG. 1. In the example illustrated in FIG. 9, a jog structure 918a on the top comb structure 906a may be coupled to one or more vias 908b-c. Additionally or alternatively, one or more other vias 908a, 908d may be coupled to the top comb structure 906a. Furthermore, the jog structure 918b on the bottom comb structure 906b may be coupled to one or more vias 908f-g. Additionally or alternatively, the bottom comb structure 906b may be coupled to one or more other vias 908e.

In some configurations, the integrated circuit 902 may include multiple levels of insulating materials and/or metal structures. For example, the metal structure 906 may be located on a fifth metal level (e.g., “metal 5”), and the vias 908 may underlie the metal structure 906. While the example of the fifth metal level is given, it should be noted that the metal structure 906 may occupy any level (e.g., any metal level) in an integrated circuit 902. In some configurations, the integrated circuit 902 may include the metal structure 906 in addition to one or more similar metal structures on one or more other levels that are coupled to the metal structure 906 (by the vias 908, for example). For instance, the integrated circuit 902 may include five metal levels with the metal structure 906 on one level and four additional metal structures similar to the metal structure 906 on the other four metal levels. The metal levels may be insulated from each other by the insulating material layer 904 and additional layers of insulating material similar to the insulating material layer 904. Additional vias similar to the vias 908 illustrated may be used to couple metal structures to each other through additional layers of insulating material.

It should be noted that line lengths (e.g., dimensions of the metal structure 906) may vary. However, longer lengths (e.g., 10,000 micrometers (μm) or more) may be more effective.

As illustrated in FIG. 9, the top comb structure 906a may be coupled to a terminal 914a and the bottom comb structure 906b may be coupled to another terminal 914b. The terminals 914a-b may be pins, couplers, etc., that allow one or more electronic devices (e.g., an ATE) to be coupled to the metal structure 906. For example, the terminals 914a-b may allow an electronic device to apply a DC voltage and/or dynamic voltage switching between the top comb structure 906a and the bottom comb structure 906b.

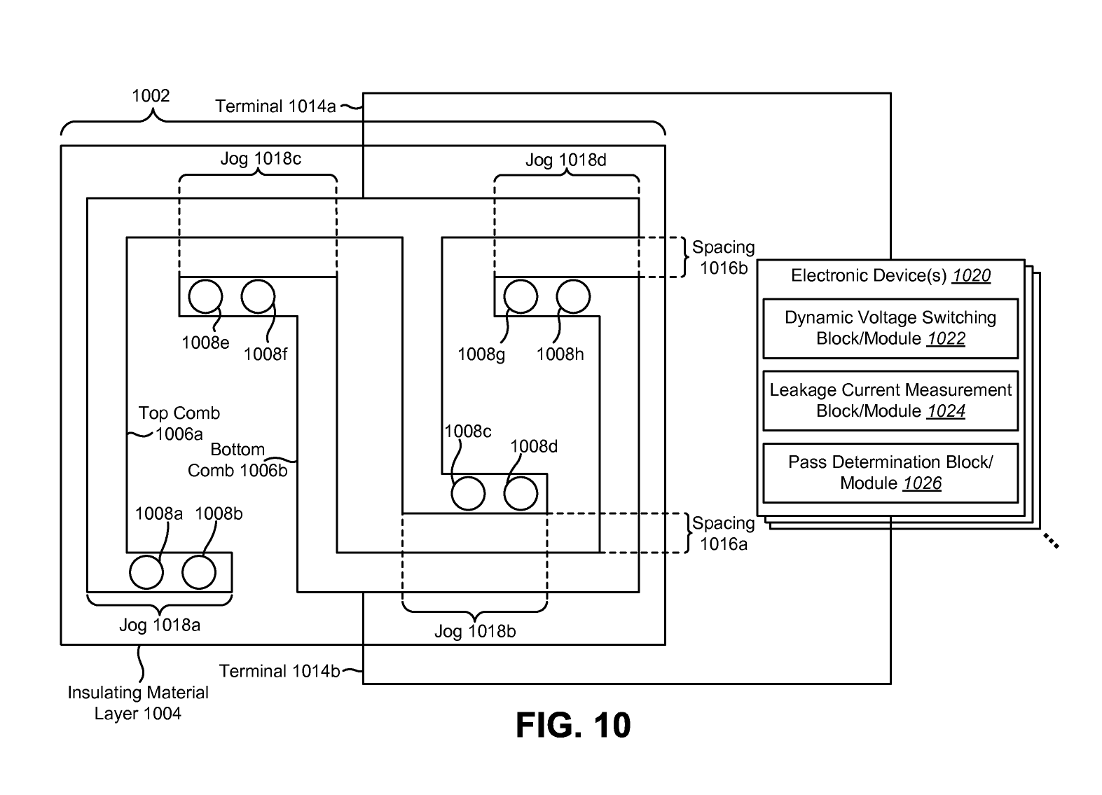

FIG. 10 is a block diagram illustrating one or more electronic devices 1020 and another example of an integrated circuit 1002 that may be used for testing insulating material. Although the one or more electronic devices 1020 are illustrated as coupled to the example of the integrated circuit 1002 in FIG. 10, the electronic device(s) 1020 may be used in conjunction with (e.g., coupled to) any other integrated circuit illustrated in the Figures described herein or others. FIG. 10 illustrates one kind of metal structure 1006 that may be used in accordance with the systems and methods disclosed herein. The integrated circuit 1002 may include an insulating material layer 1004, which may be similar to the insulating material layer 104 described in connection with FIG. 1 above.

The metal structure 1006 included in the integrated circuit 1002 may illustrate one example of jog structures. In particular, the example of the metal structure 1006 illustrated includes a top comb structure 1006a with jog structures 1018a-b and a bottom comb structure 1006b with jog structures 1018c-d. For example, a jog structure may comprise a bend, turn or angle in a metal component. The top comb structure 1006a and the bottom comb structure 1006b are located adjacent to each other and are intermingled. In one configuration, a first spacing 1016a between the comb structures 1006a-b may be a minimum line-to-line spacing allowed by design rules. Additionally or alternatively, a second spacing 1016b may be a minimum line-to-line spacing allowed by design rules.

In the example illustrated in FIG. 10, the metal structure 1006 is coupled to one or more vias 1008. For instance, the top comb structure 1006a may be coupled to four vias 1008a-d, while the bottom comb structure 1006b may be coupled to four vias 1008e-h. The vias 1008 may run through the insulating material layer 1004, which may be above or below the metal structure 1006. It should be noted that one or more of the vias 1008a-h may cause and/or include a bulge similar to the bulge 110 illustrated in FIG. 1. In the example illustrated in FIG. 10, jog structures 1018a-b on the top comb structure 1006a may be coupled to one or more vias 1008a-d. Additionally or alternatively, one or more other vias may be coupled to the top comb structure 1006a. Furthermore, the jog structures 1018c-d on the bottom comb structure 1006b may be coupled to one or more vias 1008e-h. Additionally or alternatively, the bottom comb structure 1006b may be coupled to one or more other vias.

In some configurations, the integrated circuit 1002 may include multiple levels of insulating materials and/or metal structures. For example, the metal structure 1006 may be located on a fifth metal level (e.g., “metal 5”), and the vias 1008 may underlie the metal structure 1006. While the example of the fifth metal level is given, it should be noted that the metal structure 1006 may occupy any level (e.g., any metal level) in an integrated circuit 1002. In some configurations, the integrated circuit 1002 may include the metal structure 1006 in addition to one or more similar metal structures on one or more other levels that are coupled to the metal structure 1006 (by the vias 1008, for example). For instance, the integrated circuit 1002 may include five metal levels with the metal structure 1006 on one level and four additional metal structures similar to the metal structure 1006 on the other four metal levels. The metal levels may be insulated from each other by the insulating material layer 1004 and additional layers of insulating material similar to the insulating material layer 1004. Additional vias similar to the vias 1008 illustrated may be used to couple metal structures to each other through additional layers of insulating material.

It should be noted that line lengths (e.g., dimensions of the metal structure 1006) may vary. However, longer lengths (e.g., 10,000 micrometers (μm) or more) may be more effective.

As illustrated in FIG. 10, the top comb structure 1006a may be coupled to a terminal 1014a and the bottom comb structure 1006b may be coupled to another terminal 1014b. The terminals 1014a-b may be pins, couplers, etc., that allow the one or more electronic devices 1020 (e.g., one or more testing devices) to be coupled to the metal structure 1006. For example, the terminals 1014a-b may allow an electronic device 1020 to apply a DC voltage and/or dynamic voltage switching between the top comb structure 1006a and the bottom comb structure 1006b.

The electronic device(s) 1020 may be used to test insulating material (e.g., an integrated circuit 1002). The electronic device(s) 1020 may include a dynamic voltage switching block/module 1022, a leakage current measurement block/module 1024 and/or a pass determination block/module 1026. As used herein, the term “block/module” may indicate that an element or component may be implemented in hardware, software or a combination of both. One example of an electronic device 1020 is automated test equipment (ATE). It should be noted that the dynamic voltage switching block/module 1022, the leakage current measurement block/module 1024 and/or the pass determination block/module 1026 may be included in the same electronic device 1020 and/or may be included in separate electronic devices 1020.

The dynamic voltage switching block/module 1022 may apply dynamic voltage switching to two adjacent metal components 1006a-b of the metal structure 1006. Applying dynamic voltage switching may comprise applying a voltage between two metal components that varies or switches polarity between a negative voltage and a positive voltage. This is different from the traditional approach that applies a DC voltage for testing.

The dynamic voltage switching block/module 1022 may apply voltage in accordance with one or more examples. In one example, the dynamic voltage switching block/module 1022 applies the voltage between the two adjacent metal components 1006a-b that conforms to a square wave that alternates between positive and negative voltages. In another example, the voltage applied conforms to a sinusoid that varies between positive and negative voltages. In other examples, the dynamic voltage switching block/module 1022 may apply a voltage that conforms to triangular waves, sawtooth waves and/or other signals that vary between positive and negative polarities. In some configurations, the voltage may vary in a regularly repeating pattern, with an established frequency and/or period. The frequency, period, phase and/or amplitude of the dynamic voltage switching may be varied and/or adjusted (e.g., adjustable) in some configurations.

In some configurations, the dynamic voltage switching block/module 1022 (e.g., an automatic test pattern generator) may apply dynamic voltage switching according to a test pattern. Additionally or alternatively, the dynamic voltage switching may be applied in a high temperature operating life (HTOL) test on two adjacent metal components 1006a-b in the metal structure 1006 at high speed and at elevated temperature or room temperature. For instance, the HTOL test may be performed by the electronic device(s) 1020 on an integrated circuit 1002 that was manufactured using 45 nanometer (nm) technology. Using dynamic voltage switching may enhance metal/low dielectric constant insulating layer defects more effectively than the using the DC voltage approach. It should be noted that pulse width, pulse frequency and/or pulse polarity of the dynamic voltage switching may be modulated to obtain an improved or optimized result.

The leakage current measurement block/module 1024 may measure a leakage current in the metal structure 1006 before and after dynamic voltage switching is applied to determine a leakage current change. For example, the leakage current measurement block/module 1024 may detect an amount of current flow from the first metal component 1006a to the second metal component 1006b or vice-versa. The leakage current may be measured (and recorded, for example) before the dynamic voltage switching is applied. The leakage current may also be measured by the leakage current measurement block/module 1024 after the dynamic voltage switching is applied. The leakage current measurement block/module 1024 may compare the leakage current measured after applying the dynamic voltage switching with (e.g., subtract it from) the leakage current measured before applying the dynamic switching voltage to determine a leakage current change.

The pass determination block/module 1026 may determine whether the insulating material (e.g., integrated circuit 1002) has passed a test based on the leakage current change. For example, the pass determination block/module 1026 may compare the leakage current change to a predetermined criterion for an acceptable amount of leakage current change. If the leakage current change is greater than the criterion, for example, the pass determination block/module 1026 may determine that the insulating material (e.g., integrated circuit 1002) has failed the test. However, if the leakage current change is less than or equal to the criterion, for instance, the pass determination block/module 1026 may determine that the insulating material (e.g., integrated circuit 1002) has passed the test. One or more additional or alternative predetermined criteria may be used by the pass determination block/module 1026 to determine whether the insulating material (e.g., integrated circuit 1002) has passed a test.

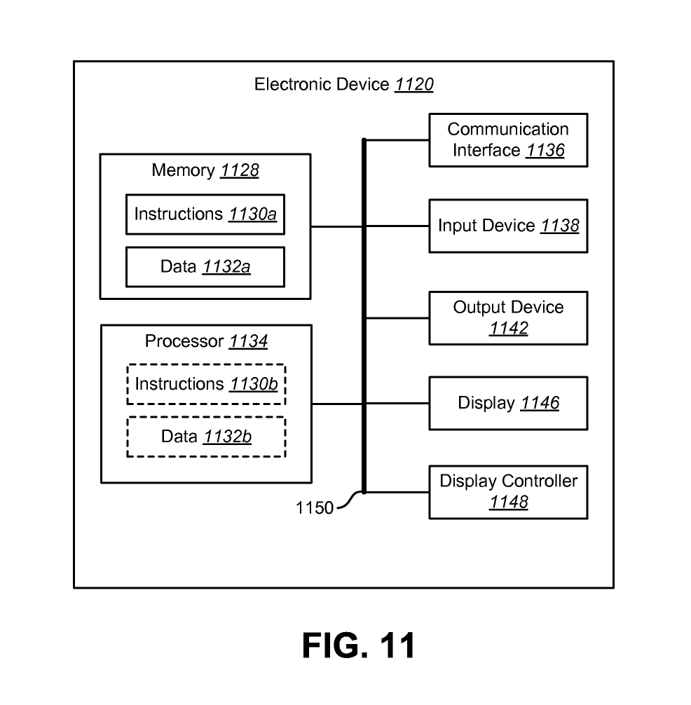

FIG. 11 illustrates various components that may be utilized in an electronic device 1120. The illustrated components may be located within the same physical structure or in separate housings or structures. The electronic device 1120 may be configured similar to the one or more electronic devices 1020 described previously. The electronic device 1120 includes a processor 1134. The processor 1134 may be a general purpose single- or multi-chip microprocessor (e.g., an ARM), a special purpose microprocessor (e.g., a digital signal processor (DSP)), a microcontroller, a programmable gate array, etc. The processor 1134 may be referred to as a central processing unit (CPU). Although just a single processor 1134 is shown in the electronic device 1120 of FIG. 11, in an alternative configuration, a combination of processors (e.g., an ARM and DSP) could be used.

The electronic device 1120 also includes memory 1128 in electronic communication with the processor 1134. That is, the processor 1134 can read information from and/or write information to the memory 1128. The memory 1128 may be any electronic component capable of storing electronic information. The memory 1128 may be random access memory (RAM), read-only memory (ROM), magnetic disk storage media, optical storage media, flash memory devices in RAM, on-board memory included with the processor, programmable read-only memory (PROM), erasable programmable read-only memory (EPROM), electrically erasable PROM (EEPROM), registers, and so forth, including combinations thereof.

Data 1132a and instructions 1130a may be stored in the memory 1128. The instructions 1130a may include one or more programs, routines, sub-routines, functions, procedures, etc. The instructions 1130a may include a single computer-readable statement or many computer-readable statements. The instructions 1130a may be executable by the processor 1134 to implement the method 300 described above. Executing the instructions 1130a may involve the use of the data 1132a that is stored in the memory 1128. FIG. 11 shows some instructions 1130b and data 1132b being loaded into the processor 1134 (which may come from instructions 1130a and data 1132a).

The electronic device 1120 may also include one or more communication interfaces 1136 for communicating with other electronic devices. The communication interfaces 1136 may be based on wired communication technology, wireless communication technology, or both. Examples of different types of communication interfaces 1136 include a serial port, a parallel port, a Universal Serial Bus (USB), an Ethernet adapter, an IEEE 1394 bus interface, a small computer system interface (SCSI) bus interface, an infrared (IR) communication port, a Bluetooth wireless communication adapter, and so forth.

The electronic device 1120 may also include one or more input devices 1138 and one or more output devices 1142. Examples of different kinds of input devices 1138 include a keyboard, mouse, microphone, remote control device, button, joystick, trackball, touchpad, lightpen, etc. Examples of different kinds of output devices 1142 include a speaker, printer, etc. One specific type of output device which may be typically included in an electronic device 1120 is a display device 1146. Display devices 1146 used with configurations disclosed herein may utilize any suitable image projection technology, such as a cathode ray tube (CRT), liquid crystal display (LCD), light-emitting diode (LED), gas plasma, electroluminescence, or the like. A display controller 1148 may also be provided, for converting data stored in the memory 1128 into text, graphics, and/or moving images (as appropriate) shown on the display device 1146.

The various components of the electronic device 1120 may be coupled together by one or more buses, which may include a power bus, a control signal bus, a status signal bus, a data bus, etc. For simplicity, the various buses are illustrated in FIG. 11 as a bus system 1150. It should be noted that FIG. 11 illustrates only one possible configuration of an electronic device 1120. Various other architectures and components may be utilized.

In the above description, reference numbers have sometimes been used in connection with various terms. Where a term is used in connection with a reference number, this may be meant to refer to a specific element that is shown in one or more of the Figures. Where a term is used without a reference number, this may be meant to refer generally to the term without limitation to any particular Figure.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The functions described herein may be stored as one or more instructions on a processor-readable or computer-readable medium. The term “computer-readable medium” refers to any available medium that can be accessed by a computer or processor. By way of example, and not limitation, such a medium may comprise RAM, ROM, EEPROM, flash memory, CD-ROM or other optical disk storage, magnetic disk storage or other magnetic storage devices, or any other medium that can be used to store desired program code in the form of instructions or data structures and that can be accessed by a computer or processor. Disk and disc, as used herein, includes compact disc (CD), laser disc, optical disc, digital versatile disc (DVD), floppy disk and Blu-ray® disc where disks usually reproduce data magnetically, while discs reproduce data optically with lasers. It should be noted that a computer-readable medium may be tangible and non-transitory. The term “computer-program product” refers to a computing device or processor in combination with code or instructions (e.g., a “program”) that may be executed, processed or computed by the computing device or processor. As used herein, the term “code” may refer to software, instructions, code or data that is/are executable by a computing device or processor.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An integrated circuit, comprising:
an insulating material layer;
a metal structure; and
a via through the insulating material layer that is coupled to the metal structure for testing insulating material by applying dynamic voltage switching to two adjacent metal components of the metal structure.

2. The integrated circuit of claim 1, wherein the metal structure comprises a meander.

3. The integrated circuit of claim 1, wherein the metal structure comprises a comb structure.

4. The integrated circuit of claim 1, wherein the metal structure comprises a jog structure.

5. The integrated circuit of claim 1, wherein the integrated circuit comprises a plurality of vias coupled to the metal structure through the insulating material layer.

6. The integrated circuit of claim 1, further comprising one or more additional metal structures on one or more additional levels, wherein the metal structure is coupled to the one or more additional metal structures by the via.

7. The integrated circuit of claim 1, wherein testing the insulating material further comprises:
measuring a leakage current from the metal structure before and after applying dynamic voltage switching to determine a leakage current change; and
determining whether the insulating material has passed a test based on the leakage current change.

8. The integrated circuit of claim 7, wherein applying dynamic voltage switching comprises applying voltage that varies between a positive voltage and a negative voltage between the two adjacent metal components.

9. The integrated circuit of claim 7, wherein applying dynamic voltage switching comprises applying voltage that conforms to one of a group consisting of a square wave, a sinusoid, a triangle wave and a sawtooth wave.

10. The integrated circuit of claim 1, wherein the insulating material is included in a wafer.

11. An apparatus, comprising:
means for testing insulating material, comprising:
means for insulating a metal structure;
means for coupling the metal structure through the means for insulating the metal structure; and
means for applying dynamic voltage switching to two adjacent metal components of the metal structure.

12. The apparatus of claim 11, wherein the metal structure comprises a meander.

13. The apparatus of claim 11, wherein the metal structure comprises a comb structure.

14. The apparatus of claim 11, wherein the metal structure comprises a jog structure.

15. The apparatus of claim 11, wherein a plurality of vias is coupled to the metal structure through the means for insulating the metal structure.

16. The apparatus of claim 11, wherein the metal structure is coupled to one or more additional metal structures on one or more additional levels through the means for insulating the metal structure.

17. The apparatus of claim 11, wherein the means for testing the insulating material further comprises:
means for measuring a leakage current from the metal structure before and after applying dynamic voltage switching to determine a leakage current change; and
means for determining whether the insulating material has passed a test based on the leakage current change.

18. The apparatus of claim 17, wherein the means for applying dynamic voltage switching comprises means for applying voltage that varies between a positive voltage and a negative voltage between the two adjacent metal components.

19. The apparatus of claim 17, wherein the means for applying dynamic voltage switching comprises means for applying voltage that conforms to one of a group consisting of a square wave, a sinusoid, a triangle wave and a sawtooth wave.

20. The apparatus of claim 11, wherein the insulating material is included in a wafer.

21. A method for testing insulating material, comprising:
applying dynamic voltage switching to two adjacent metal components of a metal structure in an integrated circuit;
measuring a leakage current from the metal structure before and after applying dynamic voltage switching to determine a leakage current change; and
determining whether insulating material has passed a test based on the leakage current change.

22. The method of claim 21, wherein the integrated circuit comprises:
an insulating material layer;
the metal structure; and
a via through the insulating material layer that is coupled to the metal structure for testing the insulating material.

23. The method of claim 21, wherein applying dynamic voltage switching comprises applying voltage that varies between a positive voltage and a negative voltage between the two adjacent metal components.

24. The method of claim 21, wherein applying dynamic voltage switching comprises applying voltage that conforms to one of a group consisting of a square wave, a sinusoid, a triangle wave and a sawtooth wave.

25. The method of claim 21, wherein determining whether the insulating material has passed the test comprises comparing the leakage current change to a predetermined criterion.

26. A computer-program product for testing insulating material, comprising a non-transitory tangible computer-readable medium having instructions thereon, the instructions comprising:
code for causing an electronic device to apply dynamic voltage switching to two adjacent metal components of a metal structure in an integrated circuit;
code for causing the electronic device to measure a leakage current from the metal structure before and after applying dynamic voltage switching to determine a leakage current change; and
code for causing the electronic device to determine whether insulating material has passed a test based on the leakage current change.

27. The computer-program product of claim 26, wherein the integrated circuit comprises:
an insulating material layer;
the metal structure; and
a via through the insulating material layer that is coupled to the metal structure for testing the insulating material.

28. The computer-program product of claim 26, wherein the code for causing the electronic device to apply dynamic voltage switching comprises code for causing the electronic device to apply voltage that varies between a positive voltage and a negative voltage between the two adjacent metal components.

29. The computer-program product of claim 26, wherein the code for causing the electronic device to apply dynamic voltage switching comprises code for causing the electronic device to apply voltage that conforms to one of a group consisting of a square wave, a sinusoid, a triangle wave and a sawtooth wave.

30. The computer-program product of claim 26, wherein the code for causing the electronic device to determine whether the insulating material has passed the test comprises code for causing the electronic device to compare the leakage current change to a predetermined criterion.
